(19) United States
(12) Patent Application Publication
(10) Pub. No.: US 2011/0157801 A1
(43) Pub. Date: Jun. 30, 2011

(54) Electronic Device Docking System

(76) Inventor: Johnny A. Satterfield, Northridge, CA (US)

(21) Appl. No.: 13/062,633

(22) PCT Filed: Sep. 4, 2009
(86) PCT No.: PCT/US09/56107

§ 371 Date: Mar. 7, 2011

Related U.S. Application Data
(60) Provisional application No. 61/094,836, filed on Sep. 5, 2008.

(51) Int. Cl. H01R 13/44; H05K 7/00; H05K 13/04

(52) U.S. Cl. 361/679.01; 439/131; 29/825

(57) ABSTRACT

A system and method disclose a docking device for allowing contents of a hand-held electronic device to be viewed on a monitor screen and/or heard through head phones of an aircraft's in-flight entertainment system. The docking device is movable between stowed and deployed positions.

### BACKGROUND OF THE INVENTION

The present invention relates generally to docking systems. More particularly, the present invention relates to a docking station for an electronic device.

With each passing year, commercial airline companies strive to provide improved services for their customers as well as to improve passenger comfort and convenience. On many airlines, it is standard for each passenger to have their own personal video display monitor associated with their chair or seat to provide the passenger with in-flight entertainment and/or information. Each seat also has a head phone jack associated with it to provide passengers with sound (i.e., when a head phone is plugged into the head phone jack) to accompany images displayed on the monitor. In-flight entertainment systems provide passengers with access to video and audio channels. However, there is an increasing demand for passengers to be able to bring their own entertainment content (music, video, movies etc.) on board commercial aircraft. Many airline passengers already bring on-board the aircraft an array of portable, hand-held electronic devices capable of storing and playing music, video and entertainment digital files. These electronic devices include, without limitation, various digital video/audio players (e.g., MP3 players, iPods, iPhones, etc.) that include a small display screen. Rather than view or listen to the pre-packaged entertainment provided by the airline, an airline passenger may wish to view or listen to the entertainment files he or she brought with them onto the aircraft. Furthermore, the passenger may wish to view the entertainment file(s) on the personal video display monitor associated with their chair or seat as that display may be significantly larger than the display screen of the digital video/audio player.

Attempts have been made by airlines to accommodate passengers. Some airlines supply cables to passengers that allow the passengers to connect their iPod or other similar device to their own personal video display monitor associated with their chair or seat. However, the iPods and other similar devices are not held in place by anything and the cable may get snagged by a passenger's arm or leg, sending the iPod or other similar device the cable is connected to flying or smacking into a fellow passenger or a surface that damages the iPod or other similar device (not to mention the other passenger). Therefore, there is a need for a docking station that will allow a passenger to “mount” an iPod or other similar device in a stationary location that is easily accessible and will not require more cables for the passenger to deal with and a further need for a docking station that will fold away to protect the connector from spilled drinks when not in use.

Thus, while providing cables or stationary docks to passengers to allow them to connect their electronic devices to a seatback display or the like, as described above, accommodates passengers seeking to use their electronic devices, there is room for significant improvement.

Accordingly, there is a need for a docking system for a handheld electronic device that overcomes the shortcomings of conventional solutions. There is a further need for a docking system for a handheld electronic device that is movable between stowed and deployed positions. There is also a need for a docking system for a handheld electronic device that requires a minimal amount of space during storage and deployment. There is an additional need for a docking system for a handheld electronic device that employs an automatic deployment mechanism. There is a need for a docking system that provides a stable place to hold the handheld electronic device while the passenger views the larger screen of the seatback display or the like. There is a also a need for a docking system that will protect the connectors from liquids when not in use. The present invention satisfies these needs and provides other related advantages.

### SUMMARY OF THE INVENTION

Embodiments of the present invention illustrate a docking system for a handheld electronic device that overcomes the shortcomings of conventional solutions. Embodiments of the present invention also provide a docking system for an electronic device movable between stowed and deployed positions that requires a minimal amount of space during storage and deployment. Embodiments of the present invention further provide a docking system for an electronic device that employs an automatic deployment mechanism. Additionally, embodiments of the present invention provide a stable place to hold the electronic device while the passenger views the larger screen of the seatback display or the like.

By providing a dock for passengers, passengers can not only listen to their own music, but passengers are also free watch any videos stored on one or more of their personal electronic devices (e.g., an iPod, iPhone, MP3/MP4 player, smartphones, etc.) on a screen of a monitor associated with the passenger's seat. Furthermore, passengers will also be able to listen to their own music through head phones connected to an in-flight entertainment (IFE) system.

In accordance with an illustrative embodiment of the present invention, a rotating fold-out docking portion of a docking device for a hand-held electronic device, such as a digital video/audio player (e.g., smartphones, MP3/MP4 players, iPods, iPhones, etc.) or other similar device is illustrated. The docking system includes a docking portion having a connector for matingly engaging a connector on the electronic device or other similar device. An illustrative preferred feature of this embodiment includes the ability to close or fold away the docking portion that includes the connector. Folding away the docking portion protects the connector when not in use. In the alternative, the docking portion can be non-folding. The docking portion folds out by a latch device being released, which in turn releases a torsion spring engaging the docking portion, allowing the docking portion to open in a rotating fashion. A rotary damper slows this rotational movement and produces a motorized look to the rotational movement. When not in use, the docking portion is folded away and latches automatically, protecting the connecter.

In accordance with another illustrative embodiment of the present invention, a slide-out dock of a docking device for a hand-held electronic device, such as a digital video/audio player (e.g., smartphones, MP3/MP4 players, iPods, iPhones, etc.) or other similar device is illustrated. The dock includes a docking portion having a connector for matingly engaging a connector on the electronic device. The docking portion is generally disposed within a display mount of a video arm upon which a display is mounted. An illustrative preferred feature of this embodiment includes the ability to slide the docking portion in and out of the display mount which protects the connector when not in use and provides ease of access to the connector when in use. The docking portion acts as a docking drawer or carriage which slides out by a latch device being released, which in turn releases a constant force spring engaging the docking portion, allowing the docking portion to open in a sliding fashion. A rotary damper slows this sliding movement and produces a motorized look to the sliding movement. When not in use, the docking portion is slid closed and the docking portion latches automatically, protecting the connecter.

Further features and advantages of the invention, as well as the structure and operation of various embodiments of the invention, are described in detail below with reference to the accompanying drawings.

### BRIEF DESCRIPTION OF THE DRAWINGS

The foregoing and other features and advantages of the invention will be apparent from the following, more particular description of embodiment of the invention, as illustrated in the accompanying drawings wherein like reference numbers generally indicate identical, functionally similar, and/or structurally similar elements. In such drawings:

FIG. 1 depicts a perspective view of an exemplary embodiment of a docking station according to the present invention in a stowed configuration;

FIG. 2 depicts a perspective view of the docking station of FIG. 1 in a deployed configuration;

FIG. 3 illustrates a typical configuration of a docking system embodying the present invention;

FIG. 4 illustrates a perspective view of an exemplary embodiment of a docking station according to the present invention in a deployed configuration;

FIG. 5 illustrates an exploded view of the docking station of FIG. 4;

FIG. 6 illustrates a top plan view of the docking station of FIG. 4;

FIG. 7 illustrates a rear view of the docking station of FIG. 4;

FIG. 8 illustrates a side view of the docking station of FIG. 4 in a closed configuration;

FIG. 9 illustrates the docking station of FIG. 8 with the mount bas/lid illustrated in phantom in an open configuration;

FIG. 10 depicts a perspective view of another exemplary embodiment of a docking station according to the present invention in a stowed configuration;

FIG. 11 depicts a perspective view of the docking station of FIG. 6 in a deployed configuration;

FIG. 12 illustrates a perspective view of the docking station of FIGS. 10 and 11; and

FIG. 13 illustrates an exploded view of the docking station of FIGS. 10 and 11.

### DETAILED DESCRIPTION OF AN EXEMPLARY EMBODIMENT OF THE PRESENT INVENTION

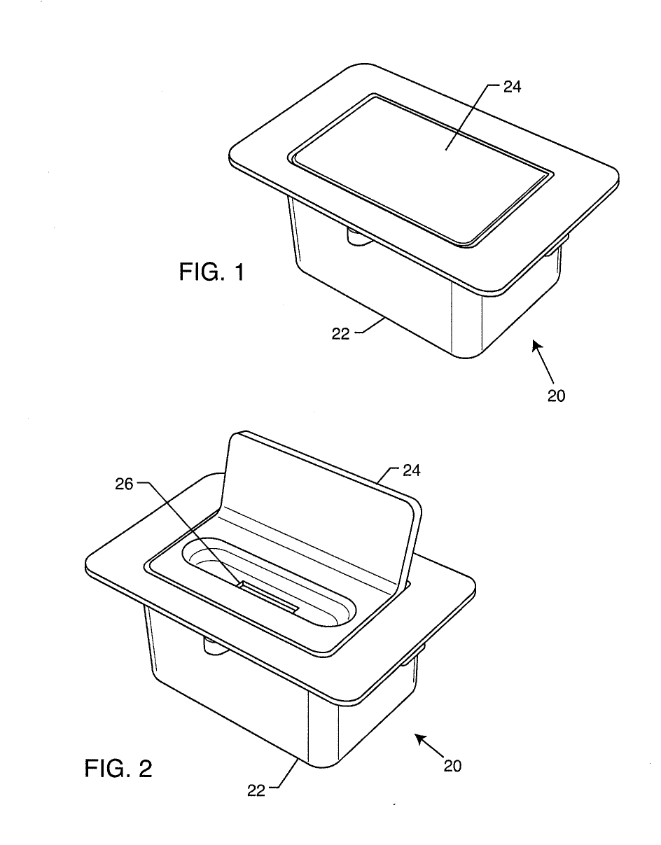

In accordance with an embodiment of the present invention, as seen in FIGS. 1-2, a docking device 20 for an electronic device, such as a digital video/audio player (e.g., smartphones, MP3/MP4 players, iPods, iPhones, etc.) or other similar device, is illustrated. The docking device 20 includes a mounting base 22 comprising a generally rectangular shell and a cover mounted thereon giving the appearance of a flange extending outwardly from the shell. The cover can be mounted to the shell using various mechanical or chemical fasteners (e.g., adhesives). Alternatively, the shell and cover can be integrally formed as a single piece. A generally L-shaped base hinge 24 is rotatably mounted within a central recess (not shown) of the base 22. The base hinge 24 serves as a rotatable docking portion and includes a connector mount for a multi-pin connector (connector mount and multi-pin connector being collectively described hereafter as connector 26). The multi-pin connector can be operationally connected to the connector mount by various mechanical or chemical fasteners and/or a combination of both. The connector 26 is operationally connected to the wiring harness of the IFE system for matingly engaging a connector (not shown) on a hand-held electronic device 28, such as a digital video/audio player (e.g., smartphones, MP3/MP4 players, iPods, iPhones, etc.) or other similar device. The connector 26 is positioned at the bottom center of a small recess on the base hinge 24. This recess is sized and shaped to receive at least a portion of the electronic device 28 to be docked (typically, the portion of the electronic device 28 having the connector for engaging the multi-pin connector of the IFE system) and includes a slot to accommodate engagement of the multi-pin connector and the connector on the electronic device 28. The base 22 serves as a housing for the connector 26. An illustrative feature of this embodiment includes the ability for a user to manually close or fold away the docking portion so that the multi-pin connector 26 is protected when not in use (i.e., when an electronic device 28 is not docked). The base hinge 24 is rotatably movable between open and closed positions, thereby rotating the multi-pin connector 26 between stowed and deployed positions. The user manually opens or closes the base hinge 24 by pressing against certain portions of the base hinge 24 to rotate the base hinge 24 between the open and closed positions. When the base hinge 24 is in the closed position, a portion of the L-shaped base hinge is generally planar with a top surface of the cover of the mounting base 22.

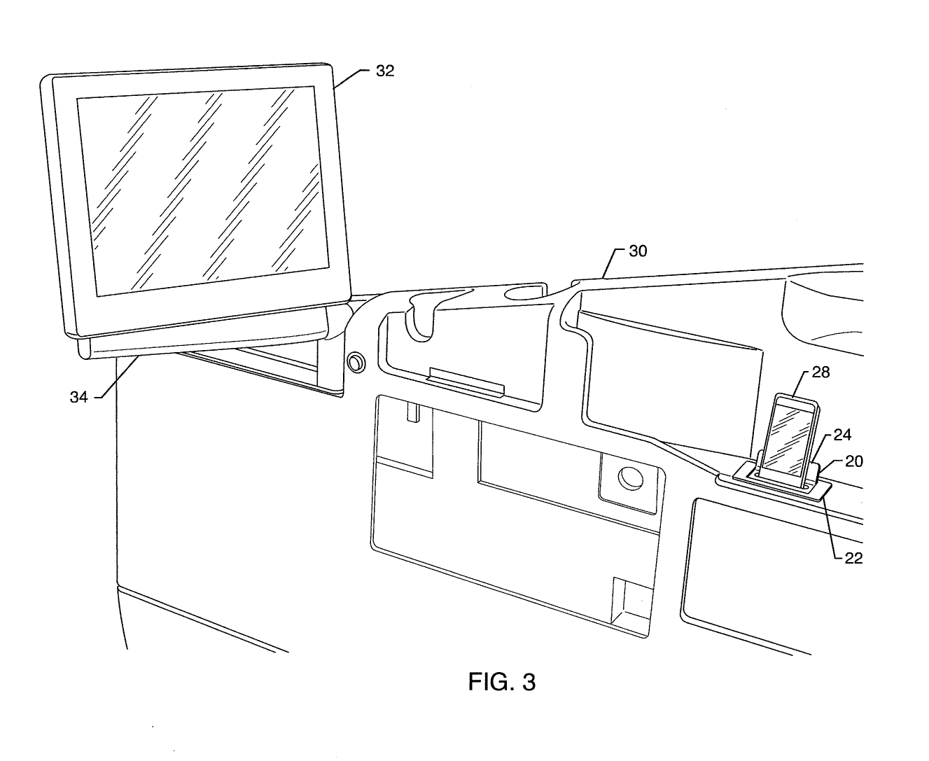

The docking device 20 can be mounted in a seat console housing 30, as seen in FIG. 3. An armrest associated with the passenger's seat may be part of the console housing 30. The multi-pin connector 26 is electronically connected by cabling/wiring (not shown) to a video monitor 32 (e.g., a flat panel monitor such as a Liquid Crystal Display (LCD) screen) mounted on an arm support 34 that may be fixed in position or movable between stowed and deployed positions. The support 34 itself is operationally connected to the console housing 30. Alternatively, the support 34 and/or the docking device 20 are attachable to any interior surface on a vehicle (e.g., aircraft, spacecraft, motor vehicle, boat, etc.) bulkhead, an exterior side of a vehicle chair or a side of a console housing or compartment located next to or part of the vehicle passenger chair.

The arm support 34 and associated monitor 32 may themselves be movable relative to each other as the arm support 34 and associated monitor 32 are moved between stowed and deployed positions with respect to the console housing 30 (e.g., a deployable video arm). A deployable video arm can be completely stowed within the console housing 30, stowed within a recess of the side of the console housing 30 or the like.

In the alternative, the docking portion can be non-folding. In this alternative, the docking portion can be part of the cover and always exposed. However, while this would still be an improvement over conventional approaches, this alternative could possibly be subjected to possible passenger abuse when not in use, and be susceptible to drink spillage; potentially creating what is commonly known as a “trash trap” (i.e., any stationary pockets in an aircraft where food, liquids, paper and the like can accumulate). In this scenario, the accumulation of trash can have an adverse affect on the performance of electronic devices as food and other debris could damage or interfere with the functioning of the pins or the like of the dock's connector.

In another alternative, instead of a single-piece base hinge 24, the connector 26 can be set within a recess of the base 22 and a lid hingedly connected to base 22.

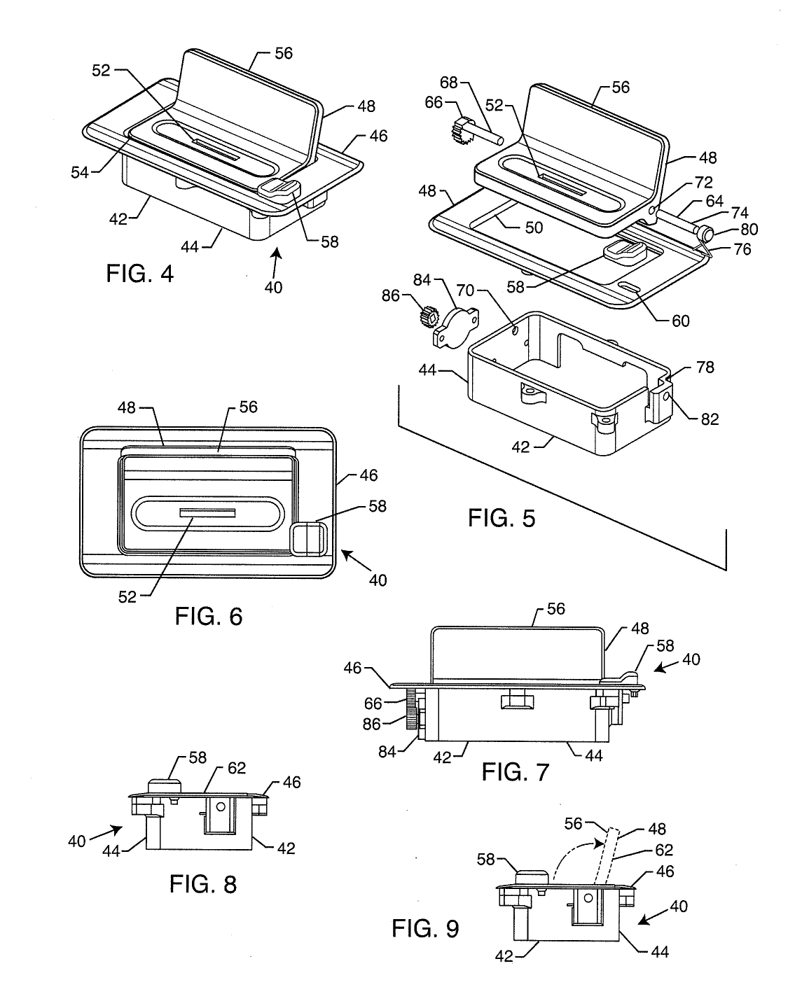

In accordance with another embodiment of the present invention, as seen in FIGS. 4-9, a docking device 40 for an electronic device, such as a digital video/audio player (e.g., smartphones, MP3/MP4 players, iPods, iPhones, etc.) or other similar device, is illustrated. The docking device 40, similar to the docking device 20 described above, includes a mounting base 42 in the form of a generally rectangular shell 44 and a cover 46 mounted thereon in a manner that gives the appearance of a flange extending outwardly from the shell 44. The cover 46 can be mounted to the shell 44 using various mechanical or chemical fasteners Alternatively, the shell 44 and cover 46 can be integrally formed as a single piece. A generally L-shaped base hinge 48 is rotatably mounted within a central recess 50 of the mounting base 42.

The base hinge 48 serves as a rotatable docking portion and includes a connector mount for a multi-pin connector (connector mount and multi-pin connector being collectively described hereafter as connector 52). The multi-pin connector can be operationally connected to the connector mount by various mechanical or chemical fasteners and/or a combination of both. The connector 52 is operationally connected to the wiring harness of the IFE system and matingly engages a connector (not shown) on the hand-held electronic device 28 or other similar device. The multi-pin connector 52 is mounted on a connector flange 54 of the base hinge 48. The multi-pin connector 52 is positioned at the bottom center of a small recess on the connector flange 54. This recess is sized and shaped to receive at least a portion of an electronic device to be docked and includes a slot to accommodate engagement of the multi-pin connector and the connector on the electronic device 28. The base hinge 48 also includes a cover flange 56 oriented generally ninety degrees to the connector flange 54. The mounting base 42 serves as a housing for the connector 52. Illustrative features of this embodiment includes the ability for a user to manually close or fold away the docking portion so that the multi-pin connector 52 is protected when not in use and automatically deploy the base hinge 48 to an open position so that the multi-pin connector 52 can be accessed by a user. A latch device 58, illustrated in the form of a spring-loaded button, is used to both deploy the base hinge 48 to an open position as well as to hold the base hinge 48 in a closed position.

The docking device 40 can be mounted in a seat console housing 30 associated with a particular seat in an aircraft, as seen in FIG. 3, in a manner same/similar as that described above with respect to the docking device 20. The multi-pin connector 52 is electro-mechanically connected by cabling/wiring (not shown) to the video monitor 32 mounted on the arm support 34 movable between stowed and deployed positions, as well as to the head phones associated with that particular seat. The shell 44 includes a cut-out to allow for the passage of the cabling/wiring that operationally connects the multi-pin connector 52 to the monitor and/or head phones associated with that particular seat.

In closed position, the button 58 keeps the base hinge 48 in the closed position as the bottom portion of the button slides over a top surface 62 of the cover flange 56. When the base hinge 48 is in the closed position, the top surface 62 of the cover flange 56 is then generally planar with a top surface of the cover 46 of the mounting base 42. The button 58 operationally engages a slot 60 on the cover 46 of the mounting base 42. When the base hinge 48 is released to automatically deploy into the open position, the button 58 is slid along the slot 60 in a direction away from the recess 50. Once the base hinge 48 begins to rotate towards the fully deployed position, the cover flange 56 will rotate up to between ninety and one hundred ten degrees from the its position in the closed configuration. The user manually closes the base hinge 48 by pressing against the cover flange 56 and rotating the cover flange 56 inwardly towards the recess 50. The user then slides the button 58 towards the recess 50 until a bottom portion of the button 58 slides over the top surface 62 of the cover flange 56.

The base hinge 48 is rotatably mounted to the mounting base 42 on one side by a pin hinge 64 and on the other side by a gear hinge 66. A shaft 68 of the gear hinge 66 is inserted through respectively a hole 70 in the shell 44 of the mounting base 42 and into a hole 72 of the base hinge 48 aligned with the hole 70 of the shell 44. One end of a shaft 74 of the pin hinge 64 is inserted through a hole 72 of the base hinge 48 while an opposite end of the shaft 74 engages a torsion spring hinge 76. The torsion spring hinge 76 is mounted within a recess 78 in the shell 44 with a generally cylindrical portion 80 of the torsion spring hinge 76 engaging a hole 82 in a wall of the recess 78.

In the alternative, instead of a single-piece base hinge 48, a lid hingedly connected to the cover 46 can be used in place of the cover flange 56 and the connector 52 can be positioned within the shell 44 instead of using the connector flange 54.

An illustrative feature of this embodiment includes the ability to close or fold away the multi-pin connector 52, as described above. Folding away the docking portion protects the multi-pin connector 52 when not in use. When the button 58 is slid away from the recess 50, the docking portion folds out, which in turn releases the torsion spring allowing the docking portion to open in a rotating fashion. When the button 58 is slid along the slot 60 in a direction away from the recess 50 to move the base hinge 48 into the open position, the torsion spring hinge 76 rotates the base hinge 48 to the open position. During the movement of the base hinge 48 to the open position, the rotation of the gear hinge 66 is slowed by a rotary damper 84 and gear damper 86 mounted to the shell 44. The rotary and gear dampers 84, 86 act as a brake and slow the rotating movement, producing a motorized look to the rotating movement.

When the multi-pin connector 52 is not in use, the docking portion is folded/rotated away and latches automatically, protecting the connecter 52. The docking device 40 includes a mechanism for preventing travel of the base hinge 48 between the stowed and deployed configurations in general and for preventing travel of the base hinge in a first direction (i.e., from the stowed position to the deployed position) in particular. The mechanism for preventing travel may come in various forms including, without limitation, a latching mechanism or the like that includes the spring-loaded button (e.g., the underside of the button 58) which can be released by sliding the button 58 away from the recess 50. When the button 58 is moved, the latching mechanism is released and the torsion spring hinge 76 rotates the docking portion to the open or deployed configuration. During deployment between the stowed and deployed configurations, rotation of the docking portion is slowed by the rotary and gear damper 84, 86. The engagement of the button 58 and the base hinge 48 prevents the base hinge 48 from being rotated towards the deployed position by the torsional spring. The button 58 can be selectively disengaged by a mechanism, allowing the base hinge 48 to rotate towards the deployed position. Alternatively, the mechanism can be in the form of the button 58 being operatively connected to a latch by a mechanical linkage where pressing the button moves the linkage which, in turn, pivots the latch away from engaging the base hinge 48, disengaging the latch from the base hinge 48 and freeing the base hinge 48 to rotate between the stowed and deployed positions. In the alternative, the mechanism may disengage the latch and the base hinge 48 by a passenger pushing the base hinge 48 inwardly towards the central recess 50 which, in turn, pivots the latch away from the base hinge 48, disengaging the latch from the base hinge 48. Once the spring-loaded latch is disengaged from the base hinge 48 and the base hinge 48 rotates away from the stowed position, the latch will automatically pivot back to the position the latch was in when the latch engaged the base hinge 48. However, the latch will not engage the base hinge 48 as the base hinge 48 has rotated away from the stowed position.

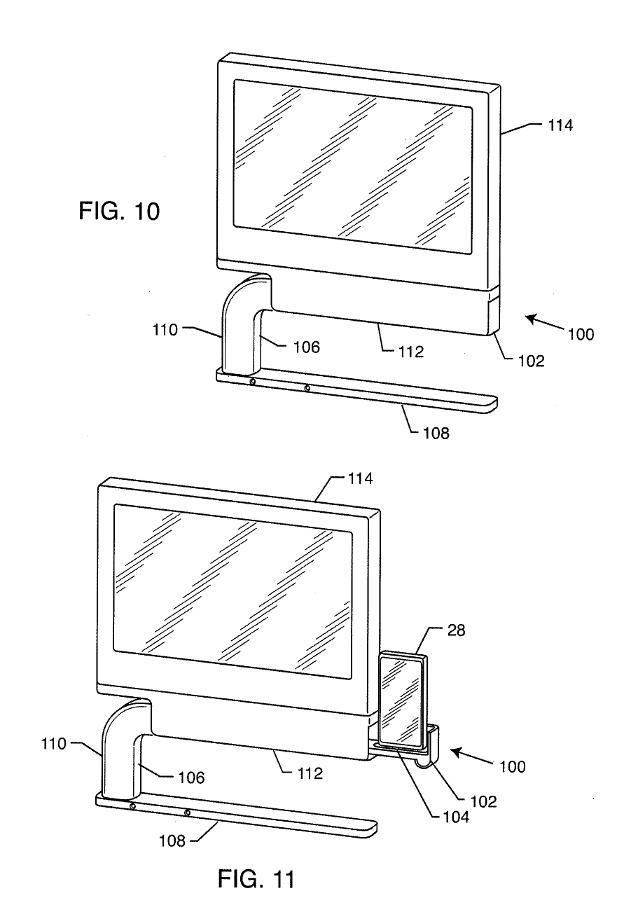

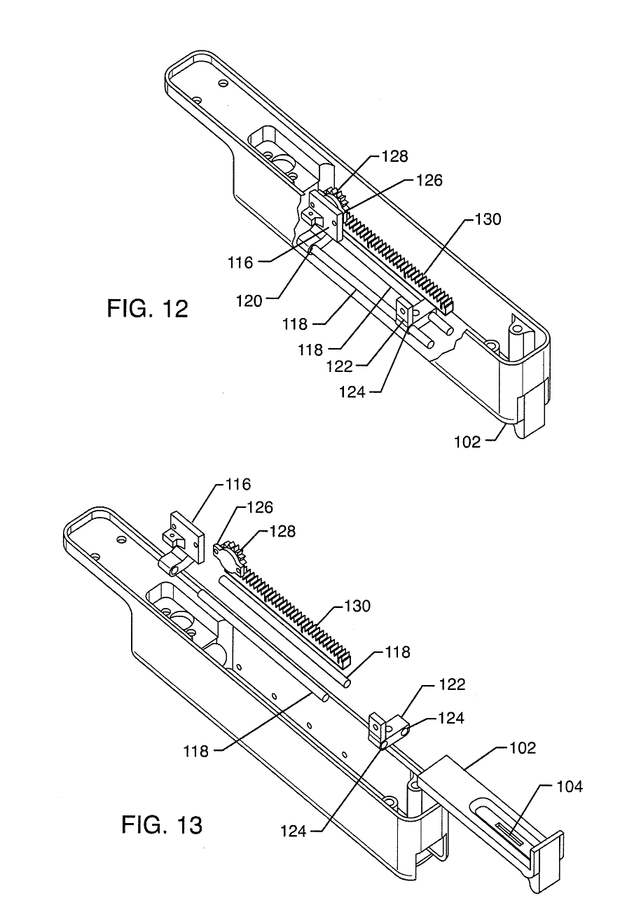

In accordance with a further embodiment of the present invention, as seen in FIGS. 10-13, a slide-out docking device 100 for an electronic device, such as a hand-held digital video/audio player (e.g., smartphones, MP3/MP4 players, iPods, iPhones, etc.) or other similar device, is illustrated. The docking device 100 includes a slide-out docking portion 102 and includes a connector mount for a multi-pin connector (connector mount and multi-pin connector being collectively described hereafter as connector 104). The multi-pin connector can be operationally connected to the connector mount by various mechanical or chemical fasteners and/or a combination of both. The connector 104 is operationally connected to the wiring harness of the IFE system and matingly engages a connector (not shown) on the hand-held electronic device 28 or other similar device. The multi-pin connector 104 is positioned at the bottom center of a small recess on the docking portion 102. This recess is sized and shaped to receive at least a portion of an electronic device to be docked and includes a slot to accommodate engagement of the multi-pin connector and the connector on the electronic device.

The docking device 100 includes video monitor support 106 having a support structure or base 108 which acts as the main structural support for the entire video monitor support 106. The base 108 may come in various forms including, without limitation, an L-shaped bracket or the like. The base 108 is attachable to a surface (not shown) and a support arm 110 is operationally connected to the base 108. The surface may be a surface on a vehicle (e.g., aircraft) bulkhead, an exterior side of a vehicle chair (not shown) or a side of a console housing or compartment located next to or part of the vehicle passenger chair. The support arm 110 may further comprise a multi-axis support arm having several degrees of freedom. The support arm 110 is operationally connected to the base 108 and a hollow video monitor mounting section 112 is operationally connected to an end of the support arm 106. The monitor mounting section 112 serves as a housing for the docking portion 102. The monitor mounting section 112 may be rotatably fixed to the support arm 110. The docking portion 102, including the connector 104, is generally disposed within the monitor mounting section 112 in a stowed position. The connector 104 is disposed outside the monitor mounting section 112 when the docking portion is in the deployed position. The monitor mounting section 112 is the attachment point for a video monitor 114 (e.g., a flat panel monitor such as a Liquid Crystal Display (LCD) screen) operatively connected to the monitor mounting section 112 by fasteners (not shown) such as screws or the like. Mounting the monitor 114 to the mounting section 112 closes the open top portion of the monitor mounting section 112. The monitor mounting section 112 extends outwardly from an elbow of the support arm 106 and is generally perpendicular to the support arm 106. The monitor mounting section 112 (along with the monitor 90) rotates about a horizontal axis of the support arm 106. While the elbow has been described as being of unitary construction with the support arm 106, the elbow may be a separate part.

A pin slide brace 116 is mounted within a recess of the monitor mounting section 112. A pair of rails or guide pins 118 are mounted in parallel within one end of each guide pin 118 inserted within a respective aperture 120 of the pin brace slide 116. A pin slide 122 includes a pair of parallel bores 124 extending therethrough and is designed to engage free ends of guide pins 118 such that the free ends of the guide pins 118 slide through the bores 124 so that the pin slide 122 is slidably movable along a length of the guide pins 118. The rails or guide pins 118 form track which the pin slide 122 moves along. The docking portion 102 is operationally connected to the pin slide 122. The docking portion 102 acts as a docking drawer which slides out by a latch device (not shown) being released, which in turn releases a constant force spring (not shown) allowing the docking portion 102 to open in a sliding fashion. A rotary damper 126 is mounted to the pin slide brace 116. The rotary damper 126 is operationally connected to a gear 18 which engages a rack 130 operationally connected to the docking portion 102. The operational connection between the rotary damper 126 and the docking portion 102 (via the rack 130 and gear 128) acts as a brake and slows the sliding movement of the docking portion 102 as the docking portion slidingly moves between the stowed and deployed positions. The operational connection between the rotary damper 126 and the docking portion 102 (via the rack 130 and gear 128) also produces a motorized look to the sliding movement. Alternatively, the pin slide 122 can be of single-piece construction with the docking portion 102.

When the multi-pin connector 104 is not in use, the docking drawer 102 is slid closed and the docking drawer 102 latches automatically, protecting the multi-pin connecter 104. The monitor support section 112 includes a mechanism for preventing travel of the docking drawer 102 between the stowed and deployed configurations in general and for preventing travel of the docking drawer in a first direction (i.e., from the stowed position to the deployed position) in particular. The mechanism for preventing travel may come in various forms including, without limitation, a latch assembly or the like that includes a stationary, spring-loaded latch (not shown) mounted on a pivot axle. The pivot axle extends outwardly from a base mounted to a surface on the interior of the monitor mounting section 112. In the stowed position, the latch engages a rod extending outwardly from the docking drawer 102. The engagement of the latch and rod prevents the docking drawer 102 from being pulled towards the deployed position by the spring. The latch can be selectively disengaged by a mechanism, allowing the docking drawer 102 (via the pin slide 122) to travel along the guide pins 118 towards the deployed position. The mechanism includes a button operatively connected to the latch by a mechanical linkage. Pressing the button moves the linkage which, in turn, pivots the latch away from the rod, disengaging the latch from the rod and freeing the docking drawer 102 to travel along the guide pins 118 between the stowed and deployed positions. When the latch is released, the spring will coil upon itself around a spring drum and cause the docking drawer 102 to move outwardly from the monitor mounting section 112 along the pin guides 118 from one end of the pin guides 118 to the other (i.e., the stowed position to the deployed position). In the alternative, the mechanism may disengage the latch and rod by a passenger pushing the docking drawer 102 inwardly on the monitor mounting section 112 which, in turn, pivots the latch away from the rod, disengaging the latch from the rod. Once the spring-loaded latch is disengaged from the rod and the docking drawer 102 moves away from the stowed position, the latch will automatically pivot back to the position the latch was in when the latch engaged the rod. However, the latch will not engage the rod as the rod has moved with the docking drawer 102 away from the stowed position.

The multi-pin connector 104 is electro-mechanically connected by cabling/wiring (not shown) to the video monitor 114 mounted on the monitor mounting section 112, as well as to the head phones associated with that particular seat. Cabling/wiring from the monitor mounting section 112 can pass into a central aperture (not shown) of the support arm 110 and through an aperture (not shown) in the base 108 to connect with the aircraft's in-flight entertainment system.

In the alternative, the docking portion can be permanently exposed. However, a permanently exposed dock, while still an improvement over conventional approaches, can possibly be subjected to possible passenger abuse when not in use, and be susceptible to drink spillage; potentially creating a “trash trap.” As discussed above, the accumulation of trash can have an adverse affect on the performance of electronic devices.

In the alternative, the docking stations described above can be adapted to be used with multi-media devices, various personal digital assistants (e.g., BlackBerry devices, PALM devices, etc.), cellular telephones (e.g., iPhones, BlackBerry devices, etc.), notebook/laptop computers or devices that combine various features of the types of devices just described.

In another alternative, in addition to the connectors described above, the docking devices 20, 40, 100 can also include a USB port, an AV port or the like. For example, the connector 26, 52, 104 described above may be part of a multi-port panel so that, in addition to the iPod and iPhone connectivity, the multi-port panel includes a USB port that would enable passengers to view their own photos, read PDFs or listen to their own music via the in-flight entertainment screen. The multi-port panel provides connectivity for audio-video input to the in-flight entertainment system so that that passengers can plug-in a variety of portable media players.

In a further alternative, the multi-pin connectors associated with the docking devices 20, 40, 100 may be electro-mechanically connected by cabling/wiring (not shown) to audio speakers that are used in place of head phones, including when such speakers are built into the monitor itself.

An alternative feature of the docking devices 20, 40, 100 described above allows the passenger's electronic devices to be re-charged while docked. A multi-port panel such as the one described above would allow a variety of electronic devices (e.g., cellular telephones, personal digital assistants, multi-media players, smartphones, notebook computers, etc.) to be re-charged while docked.

Although the present invention has been discussed above in connection with use on a passenger aircraft, the present invention is not limited to that environment and may also be used on passenger trains, cars, spacecraft and other vehicles.

Although at least two embodiments have been described in detail for purposes of illustration, various modifications may be made without departing from the scope and spirit of the invention.

What is claimed:

1. A docking system comprising:
a housing having a docking portion and a connector disposed thereon, wherein the connector is movable between stowed and deployed positions; and
means for applying a force to move the connector between the stowed and deployed positions.

2. The system according to claim 1, comprising means for dampening movement of the connector between stowed and deployed positions.

3. The system according to claim 1, wherein the means for applying a force is disposed within the housing.

4. The system according to claim 1, wherein the docking portion moves along a guide as the connector travels between the stowed and deployed positions.

5. The system according to claim 1, comprising means for rotating the connector between the stowed and deployed positions.

6. The system according to claim 1, comprising means for preventing travel of the connector between the stowed and deployed positions; and means for selectively disengaging the preventing means.

7. The system according to claim 1, wherein the housing comprises a portion of a video arm.

8. The system according to claim 1, wherein the housing is mounted to a seat console.

9. A docking system comprising:
a dock having a connector engageable with a hand-held electronic device, wherein the connector is movable between stowed and deployed positions;
a display disposed on a video arm, electro-mechanically connected to the connector; and
means for applying a force to the dock between the stowed and deployed positions, moving the connector between stowed and deployed positions.

10. The system according to claim 9, comprising means for dampening movement of the connector between stowed and deployed positions.

11. The system according to claim 9, wherein the means for applying a force includes means for a constant linear force to move the connector between the stowed and deployed positions.

12. The system according to claim 11, comprising means for nearly moving the connector between the stowed and deployed positions.

13. The system according to claim 9, comprising means for rotating the connector between the stowed and deployed positions.

14. The system according to claim 9, comprising means for preventing travel of the connector between the stowed and deployed positions; and means for selectively disengaging the preventing means.

15. The system according to claim 9, wherein the video arm) comprises a video arm movable between stowed and deployed configurations.

16. A method of docking comprising steps:
deploying a dock between stowed and deployed positions;
applying a force to the dock between stowed and deployed positions;
mounting an electronic device to the dock; and
using the dock to connect the electronic device to a display.

17. The method according to claim 16, wherein the deploying step includes the step of disengaging a latch holding the dock in a stowed position.

18. A docking system for an electronic device, comprising:
a video arm having a mount for supporting a video monitor;
a dock having a connector movable between stowed and deployed positions;
means for applying a force to the dock between the stowed and deployed positions; and
means for controlling speed of the dock as the dock travels between the stowed and deployed positions, wherein the mount serves as a housing for the dock, the connector being disposed within the mount in the stowed position.

19. The system of claim 18, including means for linearly moving the connector between the stowed and deployed positions

20. The system of claim 18, including means for preventing travel of the connector between the stowed and deployed positions; and means for selectively disengaging the preventing means.
